(19) United States
(12) Patent Application Publication
(10) Pub. No.: US 2025/0102646 A1
(43) Pub. Date: Mar. 27, 2025

(54) STATISTICALLY MODELING EFFECT OF FOG ON LIDAR DATA

(71) Applicant: GM Cruise Holdings LLC, San Francisco, CA (US)

(72) Inventors: Guy Satat, Natick, MA (US); Ryan Suess, Seattle, WA (US); Michael Shagam, San Francisco, CA (US)

(21) Appl. No.: 18/473,047

(22) Filed: Sep. 22, 2023

(51) Int. Cl. G01S 7/497; G01S 17/931; G06F 30/20

(52) U.S. Cl. CPC G01S 7/497; G01S 17/931; G06F 30/20

(57) ABSTRACT

The systems and methods disclosed herein address simulating the effect of fog on a photon. One method defines a target at a position in a 3D environment and includes the steps of selecting a starting position of the photon in the 3D environment, selecting a propagation vector directed from the starting position toward the target, selecting a propagation distance, determining a new position of the photon based in part on the starting position of the photon and the propagation vector and the propagation distance, determining whether the photon is absorbed before reaching the new position and determining, if the photon has not been absorbed, whether the photon intersects the target before reaching the new position.

### BACKGROUND

### 1. Technical Field

The present disclosure generally relates to modeling of fog, especially for a Light Detection And Ranging (LiDAR) sensor of an autonomous vehicle (AV).

### 2. Introduction

An AV often uses a LiDAR sensor to detect objects in the surrounding 3D environment. This type of sensing is challenged in adverse conditions where rain and/or fog induce scattering of the light pulse emitted by the LiDAR sensor. Rain and fog consist of small spheres of water suspended in the air. Each drop scatters incident light, whether the illumination beam emitted by the LiDAR unit or the return beam reflected by an object. The effect of this scattering is a reduction in the effective range of the LiDAR unit and/or false positive signals.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings.

FIG. 1 illustrates an example AV environment, according to some aspects of the disclosed technology.

FIG. 2 illustrates how a scanning LiDAR sensor scans its environment, according to some aspects of the disclosed technology.

FIGS. 3A-3C illustrate how fog affects a LiDAR sensor, according to some aspects of the disclosed technology.

FIG. 4 depicts an example method of modeling the path of a photon, according to some aspects of the disclosed technology.

FIG. 5 depicts a 2D example of the behavior of LiDAR photons in fog, according to some aspects of the disclosed technology.

FIG. 6 depicts example effects of an isotropy parameter on the dispersion of a photon, according to some aspects of the disclosed technology.

FIG. 7 depicts example dispersions of a LiDAR beam based on the isotropy parameter, according to some aspects of the disclosed technology.

FIGS. 8A-8C depict example return ranges for select values of the isotropy parameter and mean free path, according to some aspects of the disclosed technology.

FIG. 9 depicts example simulated return classifications for select values of the isotropy parameter and mean free path, according to some aspects of the disclosed technology.

FIG. 10 is a diagram illustrating an example simulation framework, according to some aspects of the disclosed technology.

FIG. 11 is a diagram illustrating an example system environment that can be used to facilitate AV navigation and routing operations, according to some aspects of the disclosed technology.

FIG. 12 depicts an example workflow for simulating a LiDAR photon path, according to some aspects of the disclosed technology.

### DETAILED DESCRIPTION

The detailed description set forth herein is intended as a description of various example configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. It will be clear and apparent that the subject technology is not limited to the specific details set forth herein and may be practiced without these details. In some instances, structures and components are shown in block diagram form in order to avoid obscuring the concepts of the subject technology.

AV navigation systems require information about the surrounding environment in order to avoid objects/entities as well as navigate through the environment. The AV perceives objects around itself through multiple types of sensors, e.g., imaging cameras and LiDAR sensors. LiDAR sensing is degraded in adverse conditions, e.g., where fog induces scattering of the projected illumination beam and may create a reflected signal that is interpreted by the LiDAR unit as a return, with a reported range, when there is physically no target present at the reported range. Fog consists of polydisperse droplets having diameters on the order of 1 to 100 microns. Any direct ray from the source of light is scattered by a drop but not uniformly, partly by external and partly by internal reflection. A portion of the energy of the light is also absorbed by each droplet of water that, with enough encounters of water droplets, may terminate the light before it reaches a target or on the return path the LiDAR unit. Understanding the nature of the effect of fog on a LiDAR system is critical to improving real-world performance.

The systems and methods disclosed a method of modeling the effect of fog on light, e.g., statistically simulating the behavior of an individual photon that has been emitted by a LiDAR system. The distances between interactions with water droplets are statistically modeled, the degree of deflection of the photon by each interaction is statistically modeled, and the chances of absorption are statistically modeled. A Monte Carlo simulation is performed to determine whether the photon intersects a target or misses the target, i.e., the photon is lost. Aggregation of repetitive simulations provides a representative input to the AV navigation system that can be used to develop and/or train it to properly respond in a foggy environment.

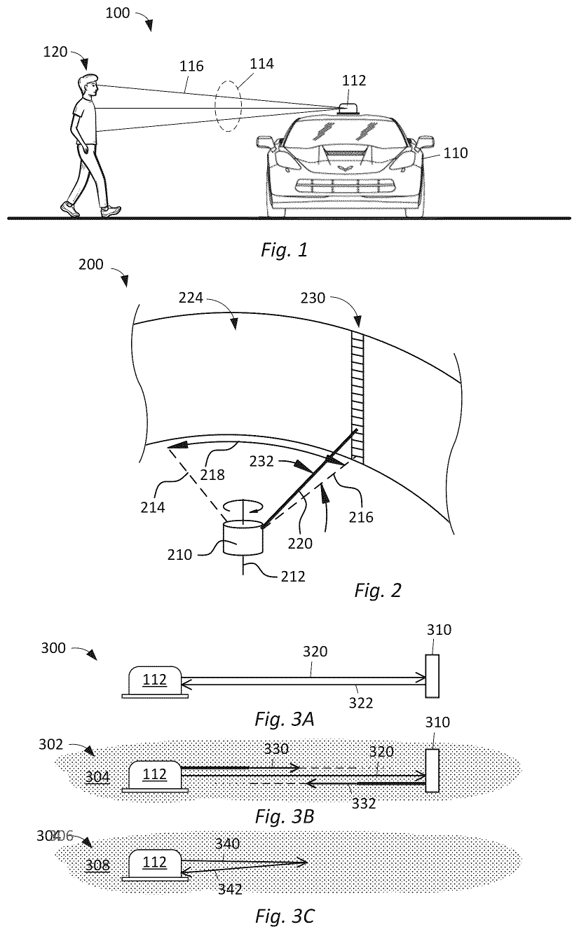

FIG. 1 illustrates an example AV environment 100, according to some aspects of the disclosed technology. A LiDAR system 112 is disposed on a vehicle 110 (e.g., an AV) and configured to emit an array 114 of light beams 116 and detect a return of each light beam 116 if reflected by a target 120, e.g., a person. In certain embodiments, the LiDAR system 112 comprises multiple sets of emitters and detector to simultaneously emit multiple beams 116. In certain embodiments, the LiDAR system 110 has a sparse illumination and/or detector configuration.

FIG. 2 illustrates how a scanning LiDAR sensor 210 scans its environment 200, according to some aspects of the disclosed technology. The sensor 210 rotates about an axis 212 within the LiDAR system 112 that is fixed to the AV 110. In certain embodiments, each emitter of the emitter/receiver array (not visible in FIG. 2) emits an illuminating beam 220 at a common rotational angle 218 from the fixed rotational reference line 214 and at an individual vertical angle 232 from the rotating reference line 216. In this depiction, each beam 220 is associated with a single point of the vertical swath 230. Detection of a return beam indicates that there is a target along the respective light beam 220. As the LiDAR sensor 210 rotates, it will scan the entire cylindrical surface 224, i.e., the field-of-view (FOV) of the LiDAR sensor 210. A data set containing the return beam intensity and TOF for all points of all the vertical swaths is a “frame” of data.

The AV 110 “perceives” an object that is within the FOV 224 by evaluating the sensor outputs, e.g., each LiDAR receiver detects one or more reflections of the light pulse projected by its associated emitter. The LiDAR system 112 records the rotational and vertical angles of the beam 220 and the time-of-flight (TOF) for each reflection, i.e., the time from emission of the light beam 220 to detection of the reflection. In certain embodiments, this information is stored in an array of “bins” that are associated with predetermined rotational and vertical positions with the FOV 224. The LiDAR system 11 analyzes the reflections and determines that an object exists at a specific location, as is known to those of skill in the art, and provides a signal. In certain embodiments, the LiDAR system 112 signal comprises a “strongest return” and the associated distance from the LiDAR to the object that reflected the strongest return.

The AV 110 then attempts to classify the object that reflected the strongest return. In certain embodiments, e.g., when it is foggy, the AV 110 determines that the strongest return is associated with a reflection from the environment, e.g., fog, and classifies the return as “speckled,” which is considered noise.

FIG. 3A illustrates scenario 300 of how a LiDAR sensor 112 is intended to operate, according to some aspects of the disclosed technology. The LiDAR sensor 112 emits an illuminating beam 320 toward a target 310. The beam 320 reaches the target 310 and is reflected, creating a return beam 322 that reaches the receiver of the LiDAR sensor 112. The TOF for the beams 320 and 322 can be converted to a distance between the LiDAR sensor 112 and the target 312 by method known to those of skill in the art.

FIG. 3B illustrates scenario 302 how an illuminating beam 330 and a return beam 332 can be lost, according to some aspects of the disclosed technology. The LiDAR sensor 112 emits an illuminating beam 330 toward a target 310. The fog 304 is thick and disperses the beam 330 such that the beam 330 does not reach the target 310, thus does not create a reflection.

Alternately, the LiDAR sensor 112 emits an illuminating beam 320 toward the target 310. The beam 320 reaches the target 310 and is reflected, creating a return beam 332 directed toward the LiDAR sensor 112. The fog 304 disperses the return beam 332 such that the receiver does not detect a return.

In both cases, the LiDAR sensor 112 does not detect a return even though there is a physical target 310 within the nominal range of the LiDAR sensor 112. This is considered a “false negative” return.

FIG. 3C illustrates how fog can create a return, according to some aspects of the disclosed technology. The LiDAR sensor 112 emits an illuminating beam 340. There is no target on the path of the beam 340 within the nominal range of the LiDAR sensor 112, which should result in no return being detected by the receiver associated with beam 340. In this scenario, however, a portion of the fog 308 is so thick that it reflects enough of the beam 340 to create a return beam 342 toward the receiver associated with beam 340. The return beam 342 is strong enough to be detected by the receiver and a time-of-flight is recorded, even though there is no physical target within the nominal range of the LiDAR sensor 112. This is considered a “false positive” return.

It is possible to review the LiDAR records and recorded visual images at a later time and determine which returns are “true,” e.g., either a negative return when there is no object in range or a positive return from a physical object, false negative, or false positive. Representative records of the LiDAR signals collected from operation in the real world, and the associated presence/absence of targets and their computed distances, are considered “road data.”

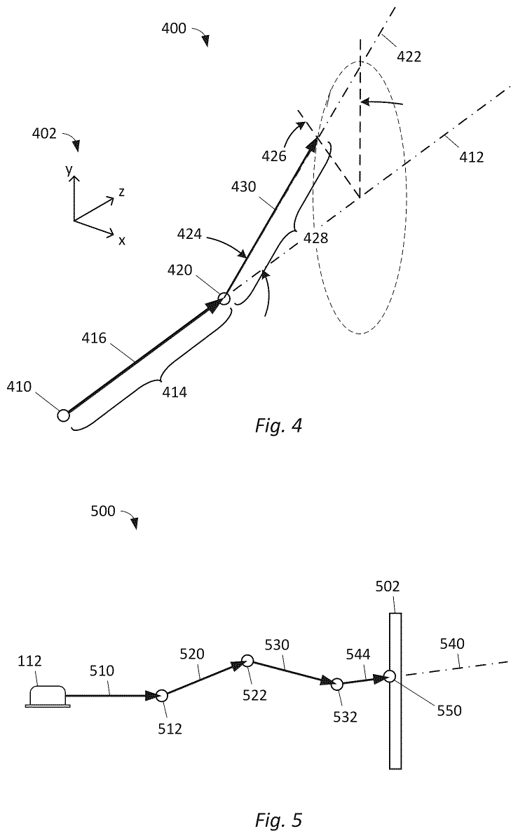

FIG. 4 depicts a graphical representation 400 of an example method of statistically modeling the path of a photon, according to some aspects of the disclosed technology. The environment has a 3D coordinate system 402. The photon has a starting position 410. A propagation vector 412 is selected. In certain embodiments, the photon is emitted by a LiDAR unit (not shown in FIG. 4), and the starting position 410 is an exterior surface of the LiDAR unit and the propagation vector 412 is aligned with an output axis of an emitter of the LiDAR unit.

A distance 414 is selected. In certain embodiments, the environment contains a “participating media” in which both scattering and absorption occur. There is a random propagation mean free path (MFP) distance before an absorbing event and a different MFP for a scattering event. The inverse of these MFPs are the absorption and scattering coefficients that, in certain embodiments, are grouped together as an “extinction coefficient” because they both cause signal loss. The distance 414 is a random number selected from a distribution having a mean that is equal to the MFP to the next scattering event. In certain embodiments, the mean free path is ⅓ of the “environmental visibility” as known to those of skill in the art. For example, runway visibility is conventionally defined as 0.05=exp(−V/M) where V is the visibility range and M is the MFP, which can be reduced to M˜V/3. In certain embodiments, the distance 414 is selected from a distribution of distances, e.g., an exponential distribution based on one or more of road data and analysis. In certain embodiments, a statistical determination is made whether the photon is absorbed by the dispersive medium, e.g., a number that is randomly selected from a range is compared to a threshold associated with the range and the photon is terminated under certain conditions of the comparison. If the photon is not absorbed, a new position 420 is determined based in part on the starting position 410, the propagation vector 412, and the propagation distance 414.

The scattering of the photon by the dispersive medium at position 420 is statistically modeled by selection of a new propagation vector 422 and a new distance 424. Although FIG. 4 depicts only a single secondary position 420, the concepts are applicable to a series of secondary positions 420 connected by distances 416, wherein the photon is scattered as described below at each secondary position 420.

In certain embodiments, the new vector 422 is determined by selecting a deviation angle 424 and a polar angle 426. In certain embodiments, the angles 424, 426 of the example polar coordinate system are replaced with the appropriate parameters of an alternate coordinate system, e.g., an x-axis rotation and a y-axis rotation in a Cartesian coordinate system. In certain embodiments, one or more of the angles 424, 426 is selected randomly from a predetermined range. In certain embodiments, one or more of the angles 424, 426 is selected from a predetermined distribution. In certain embodiments, the distance 424 is selected using the same method as used to select distance 414. In certain embodiments, the distance 424 is the same value as distance 414.

In certain embodiments, a determination is made whether the photon is terminated at position 420. In certain embodiments, the latest position 420 of the photon is compared to a “effective range” of the LiDAR unit 112 and the initial position 410. If the separation of position 420 from position 410 is greater than the effective range of the LiDAR unit, the photon is terminated at position 420.

In certain embodiments, a determination is made whether the photon is absorbed by the participating medium by the time it reaches position 420. In certain embodiments, a value is selected from a predetermined range of values and compared to an absorption limit related to the predetermined range and the photon does not propagate from the final position 420, i.e., is absorbed, if the absorption limit is exceeded.

In certain embodiments, the number of scattering events, e.g., the number of positions 420 on the path of the photon after leaving the original position 410, is compared to a pre-determined scattering number limit for computational efficiency and the photon does not propagate from the final position 420 if the scattering number limit is exceeded.

In certain embodiments, the total distance from position 410, e.g., the sum of distances 414 to positions 420, is compared to a distance limit and the photon does not propagate from the final position 420 if the distance limit is exceeded. In certain embodiments, the distance limit is sampled from a distribution having an “absorption mean free path,” which is the mean distance a photon propagates in the modeled dispersive medium until it's absorbed.

In certain embodiments, the deviation angle 424 at the final position 420 is compared to a deviation limit, e.g., reflected backward or refracted to a degree that the photon is unlikely to hit a target within the FOV of the LiDAR unit 112, and the photon does not propagate from the final position 420 if the deviation limit is exceeded.

Within this document, a conditional evaluation of a variable, e.g., any comparison of a parameter value to a limit and any description of the comparison, e.g., “the value exceeds the limit,” covers all implementations of determining “pass” and “fail” or “within the limit” and “exceeds the limit” conditions. For example, in the case of whether a photon is absorbed as determined by a random selection of a number (V) in a range of 0-100 and comparison of the selected value V to a limit (L), the comparison can be implemented as any of (1) the photon is absorbed if V>L, (2) the photon is not absorbed if V>L; (3) the photon is absorbed if V<=L, or (4) the photon is absorbed if L1<V<L2, wherein L1 and L2 are upper and lower bounds of a limit range, or any other comparative evaluation. Identification of a single comparative evaluation herein is considered interchangeable with any other means of comparative evaluation.

In certain embodiments, the dispersive medium is modeled using an “anisotropy” parameter and the selection of the new propagation vector, which is a random selection from a probability distribution, is based in part on the anisotropy parameter. In certain embodiments, the anisotropy parameter is based in part on a Henyey-Greenstein phase function. In certain embodiments, the anisotropy parameter is selected from a predetermined range of values, e.g., from a range of 0.8-0.9 of the Henyey-Greenstein phase function.

FIG. 5 depicts a 2D example of the behavior of a LiDAR photon in fog, according to some aspects of the disclosed technology. The photon initially travels from LiDAR unit 112 along path 510 directed toward target 502 and reaches position 512. If it is determined, as described with respect to FIG. 4, that the photon is not absorbed while on path 510, a new propagation vector and a new distance are selected and the photon travels along path 520 to position 522. If it is determined that the photon is not absorbed on path 520, a new propagation vector and a new distance are selected and the photon travels along path 530 to position 532. If it is determined that the photon is not absorbed up to this point, a new propagation vector and a new distance are selected and the photon travels along path 540.

In this example, the distance selected at position 532 exceeds the distance from position 532 to the target 502. The simulation identifies the intersection of path 540 and the target 502 and models the resultant position of the photon as position 550. The simulation will model the reflection of the photon from target 502. In certain embodiments, the reflection event is treated as a reflection from a diffusive Lambertian surface, i.e., a random draw occurs from a phase function cos (theta) wherein theta is the angle of incidence relative to the normal with the surface. In certain embodiments, the reflection event is treated as a specular reflection, e.g., a mirror, wherein the phase function is a delta function with the negative sign, i.e., angle in=−angle out. After the reflection, the simulation repeats the modeling process for propagation of the photon from the target 502 back to the LiDAR unit 112 in the manner described herein. In certain embodiments, one or more of the limits for absorption or termination of the return photon along the return path are modified based on the reflection. In certain embodiments, a determination is made as to whether the photon is absorbed by the target 502. In certain embodiments, the selection of the propagation vector from position 550 is based in part on the surface characteristics of target 502, e.g., whether the reflection is specular or diffusive.

The total distance from the LiDAR unit is calculated by summing the vector amplitudes, which is the round-trip distance, and divided by two to represent the target distance. The target distance may be null, or less than or greater than the actual distance to the target. The target distance is null if the photon never returns. The target distance can be less than the actual distance if the photon never reaches the target and returns only from fog. The target distance can be greater than the actual distance if the photon never reaches the target and takes a circuitous fog-only path. The target distance can be greater than the actual distance if the photon reaches the target with deviations induced by fog along its path. The target distance will only ever be exactly the actual distance if no scattering events ever occur, e.g., no fog or a very large MFP, or if the random draw from the phase function maintains the same initial vectoral angle, which tends to happen more often with large values of the G parameter. The reflectivity of the target is also a factor, as the photon will be lost if it is absorbed by the target surface. For example, if the reflectivity of the surface is 10%, there is a 10% chance the photon is reflected and a 90% chance that the photon is lost, resulting in a null target distance.

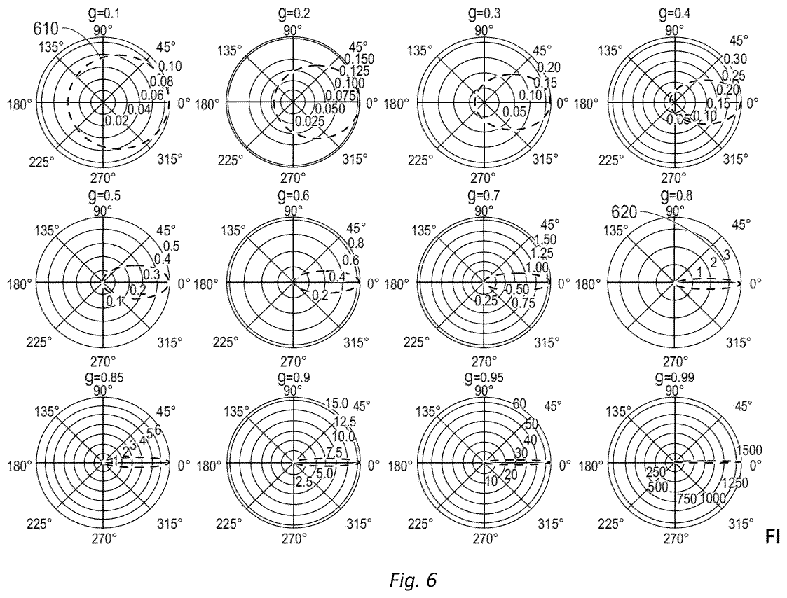

FIG. 6 depicts example effects of an anisotropy parameter on the scattering of a photon, according to some aspects of the disclosed technology. In certain embodiments, an anisotropy parameter comprises the Henyey-Greenstein phase function and is characterized by the letter “g,” which is a function of the properties of the water droplets of the fog, over a range of 0-1 that mimics the angular dependence of light scattering by small particles. In general, an environment with a g-value near zero, e.g., is very dispersive and a g-value near 1, e.g., has very little effect on light. In these polar-coordinate plots, the incident light is directed from the origin toward the zero-degree position. The mapped ellipse 610 of each plot indicates the scattering angle probability pattern. Noting that the radial scale varies across the 12 plots, the pattern 610 for g=0.1 is nearly circular with a large portion of the light reflecting backward, i.e., an angle in the range of 90-270 degrees, and the pattern 620 for g=0.8 is very directional. In certain embodiments, identification of an appropriate g-value to simulate a density of a fog, which is conventionally characterized by “visibility,” is done by empirically fitting the g-value to real-world observations, e.g., real LiDAR returns in a foggy environment.

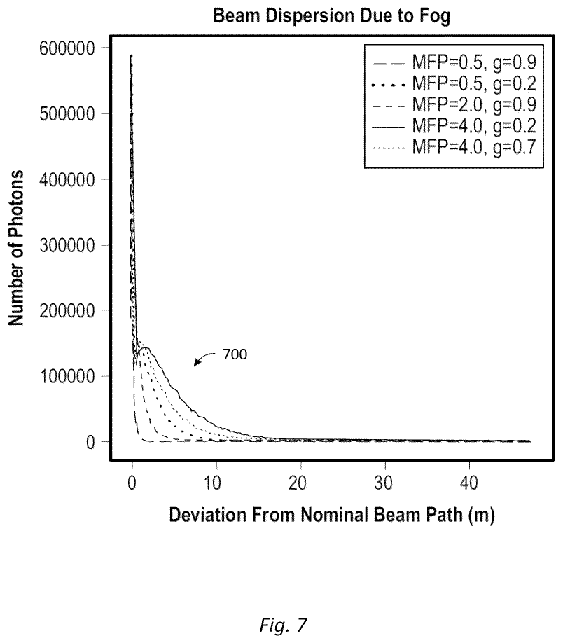

FIG. 7 depicts example dispersions of a LiDAR beam based on the anisotropy parameter, according to some aspects of the disclosed technology. The multiple curves 100 were generated for a selection of paired values of the MFP and isotropy (g) as listed in the legend of FIG. 7.

For a constant sample number of photons, the number of photons that were simulated to be deflected at incremental angles from the nominal path by each of the selected paired values are plotted against the path deviation distance. In general, the combination of a short MFP and a clear environment produces the least deflection, depicted as the curve with the sharpest corner, and the combination of a long MFP and a dispersive environment produces greater dispersion.

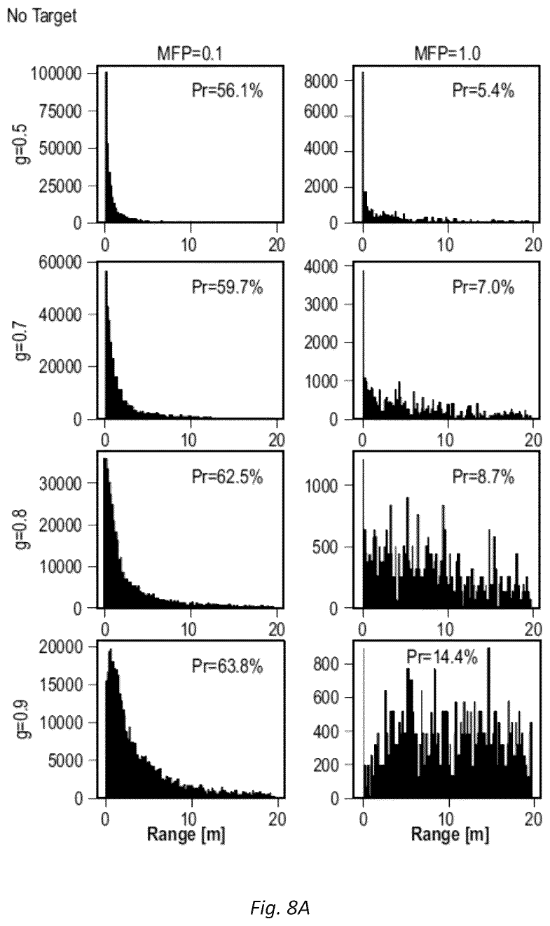

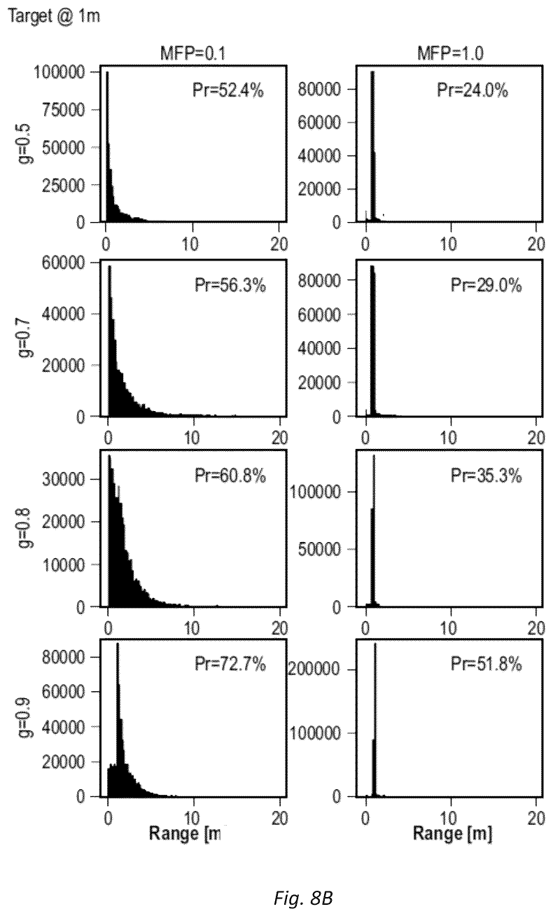

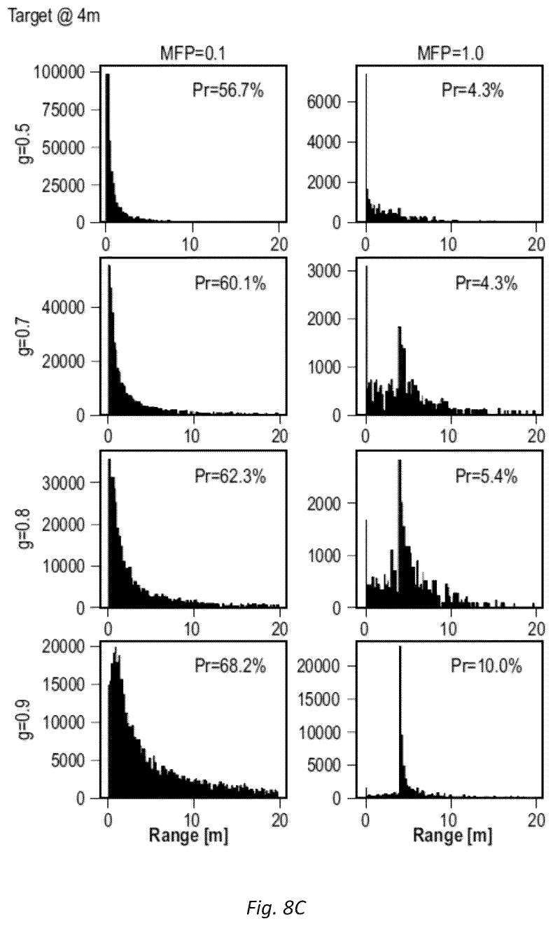

FIG. 8A depicts example return ranges for select values of the isotropy parameter and mean free path when there is no target, according to some aspects of the disclosed technology. The plots present the number of LiDAR returns at various ranges for selected paired values of MFP and g, as listed in Table 1.

TABLE 1

| Mean Free Path | Henyey-Greenstein |
|---|---|
| (MFP) | phase function (g) |
| 0.1 | 0.5 |
| 0.1 | 0.7 |
| 0.1 | 0.8 |
| 0.1 | 0.9 |
| 1 | 0.5 |
| 1 | 0.7 |
| 1 | 0.8 |
| 1 | 0.9 |

Each plot is annotated with the probability of return (Pr) that is the likelihood of the LiDAR unit providing a return range with the y-axis being the number of photons that return to the LiDAR unit (the same number of photons are launched in each plot). For example, the plot for g=0.5, MFP=0.1 (foggy) shows that the LiDAR unit will report a return 56.1% of the time, with the range having a value of 0-12 m, even though there is no real target. This is a “false positive” return. Noting that the vertical scales vary across the plots, all of the simulations indicate that a LiDAR unit will sometimes provide a false positive return in a scattering environment. The likelihood of receiving a false positive range from the 56.1% of the g=0.5, MFP=0.1 plot to 5.4% for the g=0.5, MFP=1.0 (lower density of the suspended water drops than MFP−0.1) plot. It should be noted that even in the g=0.9, MFP=1.0 plot (fairly clear environment), there are still a wide range of false-positive returns although the vertical-axis scale is 100× smaller than the g=0.5, MFP=0.1 plot.

FIG. 8B depicts example return ranges for the same anisotropy parameter and mean free path values of FIG. 8A with a target located one meter from the LiDAR unit, according to some aspects of the disclosed technology. The plot for g=0.5, MFP=0.1 (foggy) shows that the LiDAR unit will report a return 52.4% of the time, substantially the same for these condition without a target as shown in FIG. 8A, and there is no significant peak at 1 m. This indicates that, at this level of fog, a target at 1 m is not visible to the LiDAR unit.

FIG. 8C depicts example return ranges for the same anisotropy parameter and mean free path values of FIG. 8B with a target located four meters from the LiDAR unit, according to some aspects of the disclosed technology. In general, the MFP=0.1 plots all show a high fraction of returns (56.7-68.2%) but no significant peak at 4 m, indicating that most returns are false-positive returns from the fog. In contrast, the MFP=1.0 plots show a trend from g=0.05 to g=0.9 of increasing visibility of a peak at 4 m although the probability of a return is low (4.3-10%).

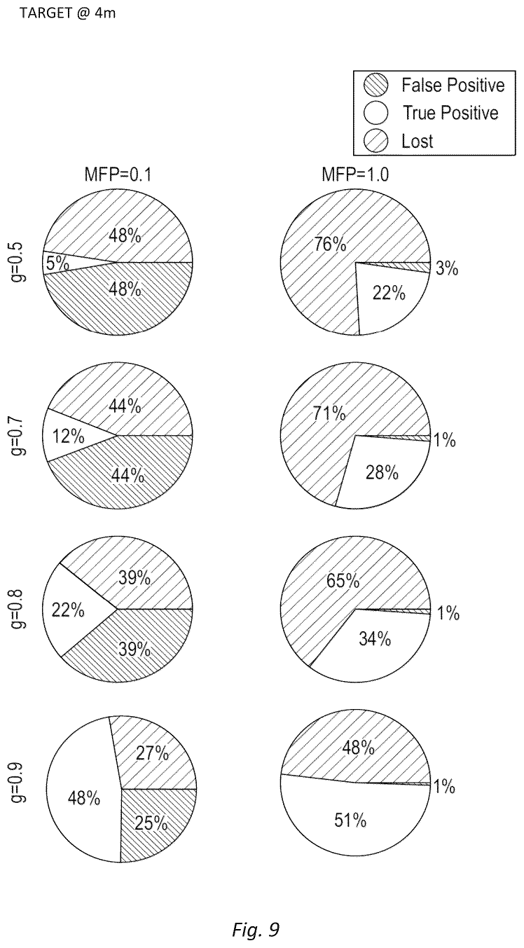

FIG. 9 depicts example simulated return classifications for selected values of the anisotropy parameter and mean free path, according to some aspects of the disclosed technology. The left column are plots for various values of g (0.5, 0.7, 0.8, 0.9) for a common MFP=0.1 m. The true-positive fraction grows as the g-value increases (the environment becomes clearer) while the false-positive and lost categories remain approximately equal. The right column of plots evaluates the effect of changing the MFP to 1.0 (less dense fog) for the same g-values. Again, the true-positive fraction increases as the g-value increases. For MFP−1.0, however, the percentage of false-positives is very low, e.g., under 2.5% even for g=0.5, and most signals are lost.

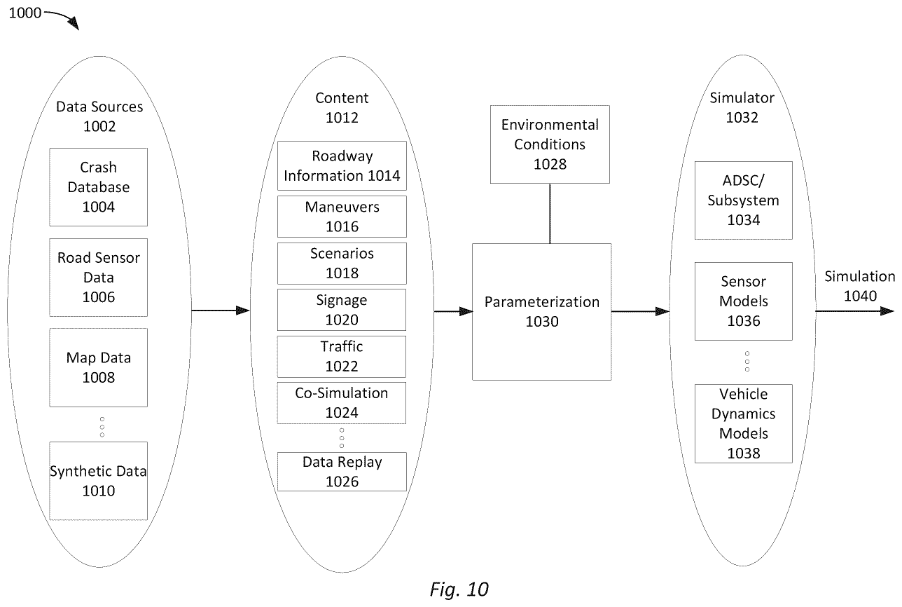

FIG. 10 is a diagram illustrating an example simulation framework 1000, according to some examples of the present disclosure. The example simulation framework 1000 includes data sources 1002, content 1012, environmental conditions 1028, parameterization 1030, and a simulator 1032. The components in the example simulation framework 1000 are merely illustrative examples provided for explanation purposes. In certain embodiments, the simulation framework 1000 includes other components that are not shown in FIG. 10 and/or more or less components than shown in FIG. 10.

In certain embodiments, the data sources 1002 are used to create a simulation. In certain embodiments, the data sources 1002 include one or more of a crash database 1004, road sensor data 1006, map data 1008, and/or synthetic data 1010. In certain embodiments, the data sources 1002 include more or less sources than shown in FIG. 10 and/or one or more data sources that are not shown in FIG. 10.

In certain embodiments, the crash databases 1004 includes crash data, e.g., data describing crashes and/or associated details, generated by vehicles involved in crashes. In certain embodiments, the road sensor data 1006 includes data collected by one or more sensors, e.g., camera sensors, LiDAR sensors, RADAR sensors, SONAR sensors, IMU sensors, GPS/GNSS receivers, and/or any other sensors, of one or more vehicles while the one or more vehicles drive/navigate one or more real-world environments. In certain embodiments, the map data 1008 includes one or more maps and, in some cases, associated data, e.g., a high-definition (HD) map, a sensor map, a scene map, and/or any other map. In some embodiments, the HD map includes roadway information, e.g., a lane width, a location of a road sign and/or a traffic light, a direction of travel for a lane, road junction information, and speed limit information.

In certain embodiments, the synthetic data 1010 includes one or more of a virtual asset, an object, and/or an element created for a simulated scene, a virtual scene, a virtual scene element, and any other synthetic data element. In certain embodiments, the synthetic data 1010 includes one or more of a virtual vehicle, a virtual pedestrian, a virtual road, a virtual object, a virtual environment/scene, a virtual sign, a virtual background, a virtual building, a virtual tree, motorcycle, a virtual bicycle, a virtual obstacle, a virtual environmental element, e.g., weather and/or lightning, a shadow, and/or a virtual surface. In certain embodiments, the synthetic data 1010 includes synthetic sensor data such as synthetic camera data, synthetic LiDAR data, synthetic RADAR data, synthetic IMU data, and/or any other type of synthetic sensor data.

In certain embodiments, data from one or more of the data sources 1002 is used to create the content 1012. In certain embodiments, the content 1012 includes static content and/or dynamic content. In certain embodiments, the content 1012 includes roadway information 1014, a maneuver 1016, a scenario 1018, signage 1020, traffic 1022, a co-simulation 1024, and/or data replay 1026. In certain embodiments, the roadway information 1014 includes one or more of lane information, e.g., number of lanes and/or lane widths and/or directions of travel for each lane, the location and information of a road sign and/or a traffic light, road junction information, speed limit information, a road attribute, e.g., surfaces and/or angles of inclination and/or curvatures and/or obstacles, road topologies, and/or other roadway information. In certain embodiments, the maneuver 1016 includes any AV maneuver and the scenario 1018 includes a specific AV behavior in a certain AV scene/environment. The signage 1020 includes one or more signs, e.g., a traffic light, a road sign, a billboard, and a message displayed on the road. In certain embodiments, the traffic 1022 includes traffic information such as traffic density, traffic fluctuations, traffic patterns, traffic activity, delays, positions of traffic, velocities, volumes of vehicles in traffic, geometries or footprints of vehicles, pedestrians, and occupied and/or unoccupied spaces.

In certain embodiments, the co-simulation 1024 includes a distributed modeling and simulation of different AV subsystems that form the larger AV system. In certain embodiments, the co-simulation 1024 includes information for connecting separate simulations together with interactive communications. In certain embodiments, the co-simulation 1024 allows for modeling to be done at a subsystem level while providing interfaces to connect the subsystems to the rest of the system, e.g., the autonomous driving system computer. In certain embodiments, the data replay 1026 includes replay content produced from real-world sensor data, e.g., road sensor data 1006.

The environmental conditions 1028 include information about environmental conditions 1028, e.g., atmospheric conditions. In certain embodiments, the environmental conditions comprise one or more of road/terrain conditions such as surface slope or gradient, surface geometry, surface coefficient of friction, road obstacles, illumination, weather, road and/or scene conditions resulting from one or more environmental conditions.

In certain embodiments, the content 1012 and the environmental conditions 1028 are used to create the parameterization 1030. In certain embodiments, the parameterization 1030 includes parameter ranges, parameterized scenarios, probability density functions of one or more parameters, sampled parameter values, parameter spaces to be tested, evaluation windows for evaluating a behavior of an AV in a simulation, scene parameters, content parameters, and environmental parameters. In certain embodiments, the parameterization 1030 is used by a simulator 1032 to generate a simulation 1040.

In certain embodiments, the simulator 1032 includes a software engine, an algorithm, a neural network model, and/or a software component used to generate simulations, such as simulation 1040. In certain embodiments, the simulator 1032 includes one or more of an autonomous driving system computer (ADSC)/subsystem model 1034, a sensor model 1036, and a vehicle dynamics model 1038. In certain embodiments, the ADSC/subsystem model 1034 includes a model, a descriptor, and/or an interface for one or more of the ADSC and/or the ADSC subsystems, e.g., a perception stack 112, a localization stack 114, a prediction stack 116, a planning stack 118, a communications stack 120, a control stack 122, a sensor system, and/or any other subsystems.

In certain embodiments, the sensor model 1036 includes a mathematical representation of a hardware sensor and an operation, e.g., sensor data processing, of one or more sensors, e.g., a LiDAR, a RADAR, a SONAR, a camera sensor, an IMU, and/or any other sensor. In certain embodiments, sensor model 1036 includes a LiDAR sensor model that simulates operation of a LiDAR sensor, e.g., a LiDAR sensor model used to simulate transmission of LiDAR beams in the simulation 1040 and simulate LiDAR measurements such as range, and/or intensity corresponding to one or more objects in the simulation 1040. In certain embodiments, the vehicle dynamics model 1038 models one or more of a vehicle behavior/operation, a vehicle attribute, a vehicle trajectory, and a vehicle position.

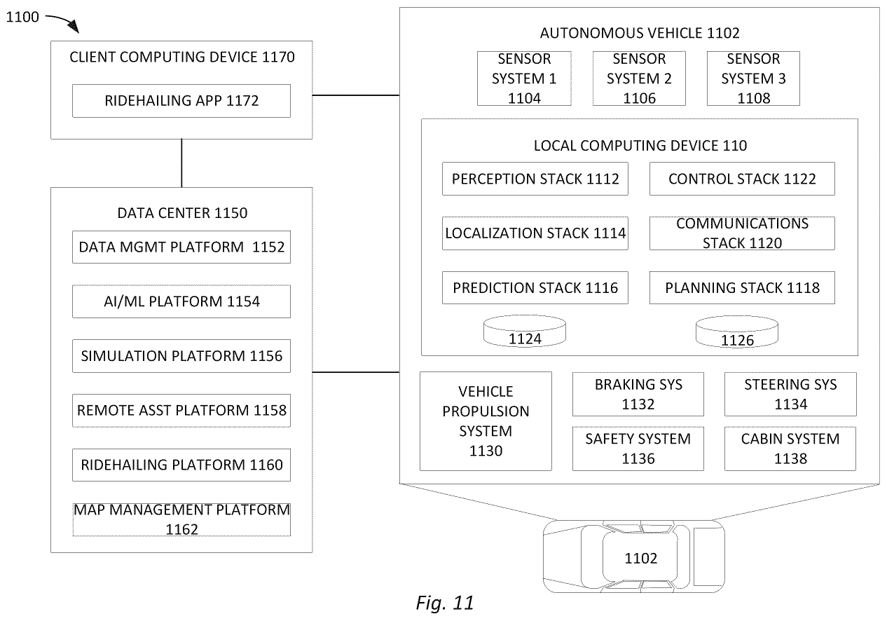

FIG. 11 is a diagram illustrating an example system environment that can be used to facilitate AV navigation and routing operations, according to some aspects of the disclosed technology. One of ordinary skill in the art will understand that, for AV environment 1100 and any system discussed in the present disclosure, there can be additional or fewer components in similar or alternative configurations. The illustrations and examples provided in the present disclosure are for conciseness and clarity. Other embodiments may include different numbers and/or types of elements that do not depart from the scope of the present disclosure.

In this example, the AV environment 1100 includes an AV 1102, a data center 1150, and a client computing device 1170. The AV 1102, the data center 1150, and the client computing device 1170 communicate with one another over one or more networks (not shown) such as a public network, e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network such as a multi-cloud or hybrid-cloud network.

In certain embodiments, the AV 1102 navigates a roadway without a human driver based on sensor signals generated by multiple sensor systems 1104, 1106, and 1108. In certain embodiments, the sensor systems 1104-1108 include one or more types of sensors arranged about the AV 1102. In certain embodiments, the sensor systems 1104-1108 include one or more of an Inertial Measurement Unit (IMU), a camera such as a still image cameras and/or a video camera, a light sensor such as a LIDAR system and/or an ambient light sensor and/or an infrared sensor, a RADAR system, a GPS receiver, an audio sensor such as a microphone and/or a SOund Navigation And Ranging (SONAR) system and/or an ultrasonic sensors, an engine sensor, a speedometer, a tachometer, an odometer, an altimeter, a tilt sensor, an impact sensor, an airbag sensor, a seat occupancy sensor, an open/closed door sensor, a tire pressure sensor, and a rain sensor. For example, the sensor system 1104 can be a camera system, the sensor system 1106 can be a LIDAR system, and the sensor system 1108 can be a RADAR system.

In certain embodiments, the AV 1102 includes a mechanical system used to maneuver or operate the AV 1102. In certain embodiments, the mechanical system includes one or more of a vehicle propulsion system 1130, a braking system 1132, a steering system 1134, a safety system 1136, and a cabin system 1138. In certain embodiments, the vehicle propulsion system 1130 includes one or more of an electric motor and an internal combustion engine. In certain embodiments, the braking system 1132 includes an engine brake, brake pads, actuators, and/or any other suitable componentry configured to assist in decelerating the AV 1102. In certain embodiments, the steering system 1134 includes componentry configured to control the direction of movement of the AV 1102. In certain embodiments, the safety system 1136 includes lights and signal indicators, a parking brake, and airbags. In certain embodiments, the cabin system 1138 includes a cabin temperature control system and/or an in-cabin entertainment system. In certain embodiments, the AV 1102 does not include one or more human driver actuators, e.g., a steering wheel, a handbrake, a brake pedal, an accelerator pedal, a turn signal lever, a window wipers control. In certain embodiments, the cabin system 1138 comprises one or more client interfaces, e.g., a Graphical User Interfaces (GUI) and/or a Voice User Interfaces (VUI), for controlling certain aspects of the mechanical systems 1130-1138.

In certain embodiments, the AV 1102 includes a local computing device 1110 that is in communication with the sensor systems 1104-1108, the mechanical systems 1130-1138, the data center 1150, and the client computing device 1170, among other systems. In certain embodiments, the local computing device 1110 comprises one or more of a processor and a memory, including instructions to be executed by the processor. In certain embodiments, the instructions comprise one or more software stacks or components responsible for controlling the AV 1102, communicating with the data center 1150 and/or the client computing device 1170 and/or and other systems, receiving inputs from riders and/or passengers and/or and other entities within the AV's environment, and logging metrics collected by the sensor systems 1104-1108. In this example, the local computing device 1110 includes a perception stack 1112, a localization stack 1114, a prediction stack 1116, a planning stack 1118, a communications stack 1120, a control stack 1122, an AV operational database 1124, and an HD geospatial database 1126.

In certain embodiments, the perception stack 1112 enables the AV 1102 to “see,” e.g., via cameras and/or LIDAR sensors, “hear,” e.g., via a microphone, and “feel,” e.g., via a pressure sensor or a force sensor or an impact sensor, its environment using information from the sensor systems 1104-1108, the localization stack 1114, the HD geospatial database 1126, other components of the AV, and other data sources, e.g., the data center 1150 and/or the client computing device 1170 and/or third party data sources. In certain embodiments, the perception stack 1112 detects and classifies an object and determines one or more of its current location, speed, and direction. In certain embodiments, the perception stack 1112 determines the free space around the AV 1102, e.g., to maintain a safe distance from other objects and/or change lanes and/or park the AV. In certain embodiments, the perception stack 1112 identifies environmental uncertainties, such as where to look for moving objects and flag areas that may be obscured or blocked from view. In certain embodiments, an output of the perception stack 1112 is a bounding area around a perceived object that is associated with a semantic label that identifies the type of object within the bounding area, the kinematic of the object, e.g., information about its movement and/or a tracked path of the object, and a description of the pose of the object, e.g., its orientation or heading.

In certain embodiments, the localization stack 1114 determines the AV's position and orientation/pose using different methods from multiple systems, e.g., GPS, IMUs, cameras, LIDAR, RADAR, ultrasonic sensors, the HD geospatial database 1126. In certain embodiments, the AV 1102 compares sensor data captured in real-time by the sensor systems 1104-1108 to data in the HD geospatial database 1126 to determine the AV's position and orientation. In certain embodiments, the AV 1102 focuses its search based on sensor data from one or more first sensor systems, e.g., the GPS, by matching sensor data from one or more second sensor systems, e.g., the LIDAR. In certain embodiments, if the mapping and localization information from one system is unavailable, the AV 1102 uses mapping and localization information from a redundant system and/or from a remote data source.

In certain embodiments, the prediction stack 1116 receives information from the localization stack 1114 and objects identified by the perception stack 1112 and predicts a future path for the objects. In certain embodiments, the prediction stack 1116 output comprises several likely paths that an object is predicted to take along with a probability associated with each path. For each predicted path, the prediction stack 1116 also provides a range of points along the path corresponding to a predicted location of the object along the path at future time intervals along with an expected error value for each of the points that indicates a probabilistic deviation from that point.

In certain embodiments, the planning stack 1118 determines how to maneuver or operate the AV 1102 safely and efficiently in its environment. In certain embodiments, the planning stack 1118 receives the location, speed, and direction of the AV 1102, geospatial data, data regarding objects sharing the road with the AV 1102, e.g., pedestrians and/or vehicles, or certain events occurring during a trip, e.g., an emergency vehicle blaring a siren and/or a street closure, traffic rules and other safety standards or practices for the road, user input, and other relevant data for directing the AV 1102 from one point to another, and outputs from the perception stack 1112, the localization stack 1114, and the prediction stack 1116. In certain embodiments, the planning stack 1118 determines one or more sets of one or more mechanical operations that the AV 1102 can perform, e.g., go straight or turn and/or accelerate or maintain a constant speed or decelerate and/or activate a blinker, and select one or more operations to meet changing road conditions and events. In certain embodiments, the planning stack 1118 selects from multiple backup plans if something unexpected happens. For example, another vehicle may aggressively cut into the destination lane while the AV 1102 is preparing to change lanes, making the lane change unsafe. In certain embodiments, the planning stack 1118 had already determined one or more alternative plans for such an event and, upon an occurrence of the unexpected event, the planning stack 1118 directs the AV 1102 to implement one of the alternative plans, e.g., go around the block, instead of blocking a current lane while waiting for an opening to change lanes.

In certain embodiments, the control stack 1122 manages the operation of one or more of the vehicle propulsion system 1130, the braking system 1132, the steering system 1134, the safety system 1136, and the cabin system 1138. In certain embodiments, the control stack 1122 receives sensor signals from the sensor systems 1104-1108 as well as communicates with other stacks or components of the local computing device 1110 or a remote system, e.g., the data center 1150, to effectuate operation of the AV 1102. In certain embodiments, the control stack 1122 implements the final path or action from the multiple paths or actions provided by the planning stack 1118. In certain embodiments, this involves turning the routes and decisions from the planning stack 1118 into commands for the actuators that control the AV's steering, throttle, brake, and drive units.

In certain embodiments, the communications stack 1120 transmits and receives signals between the various stacks and other components of the AV 1102 and between the AV 1102 and the data center 1150, the client computing device 1170, and other remote systems. In certain embodiments, the communications stack 1120 enables the local computing device 1110 to exchange information remotely over a network, e.g., through an antenna array or interface that can provide a metropolitan WIFI network connection, a mobile or cellular network connection including Third Generation (3G), Fourth Generation (4G), Long-Term Evolution (LTE), 5th Generation (5G), and/or other wireless network connection, e.g., License Assisted Access (LAA), Citizens Broadband Radio Service (CBRS), MULTEFIRE systems. In certain embodiments, the communications stack 1120 facilitates the local exchange of information, through a wired connection, e.g., a mobile computing device docked in an in-car docking station or connected via Universal Serial Bus (USB), or a local wireless connection, e.g., a Wireless Local Area Network (WLAN), Low Power Wide Area Network (LPWAN), Bluetooth®, and/or an infrared device.

In certain embodiments, the HD geospatial database 1126 stores HD maps and related data of the streets upon which the AV 1102 travels. In certain embodiments, the HD maps and related data comprise multiple layers, such as an areas layer, a lanes and boundaries layer, an intersections layer, and a traffic controls layer. In certain embodiments, the areas layer includes geospatial information indicating geographic areas that are drivable, e.g., roads and parking areas and shoulders, and areas that are not drivable, e.g., medians and sidewalks and buildings. In certain embodiments, the drivable areas constitute links or connections, e.g., drivable areas that form the same road, versus intersections, e.g., drivable areas where two or more roads intersect. In certain embodiments, the lanes and boundaries layer includes geospatial information of road lanes, e.g., lane centerline and boundaries and/or types of lane boundaries, and related attributes, e.g., direction of travel and speed limit and lane type. In certain embodiments, the lanes and boundaries layer includes three-dimensional (3D) attributes related to lanes, e.g., slope and elevation and curvature. In certain embodiments, the intersections layer includes geospatial information of intersections, e.g., crosswalks and stop lines and turning lane boundaries, and related attributes, e.g., permissive or protected/permissive or protected-only left-turn lanes, legal or illegal u-turn lanes permissive or protected-only right turn lanes. In certain embodiments, the traffic controls layer includes geospatial information about traffic signal lights, traffic signs, and other road objects and related attributes.

In certain embodiments, the AV operational database 1124 stores raw AV data generated by the sensor systems 1104-1108, stacks 1112-1122, and other components of the AV 1102 and/or data received by the AV 1102 from remote systems, e.g., the data center 1150 and the client computing device 1170. In certain embodiments, the raw AV data includes one or more of HD LIDAR point cloud data, image data, RADAR data, GPS data, and other sensor data that the data center 1150 can use for creating or updating AV geospatial data or for creating simulations of situations encountered by AV 1102 for future testing or training of various machine learning algorithms that are incorporated in the local computing device 1110.

In certain embodiments, the data center 1150 includes a private cloud, e.g., an enterprise network or a co-location provider network, a public cloud, e.g., an IaaS network, a PaaS network, a SaaS network, a Cloud Service Provider (CSP) network, a hybrid cloud, a multi-cloud, and/or any other network. In certain embodiments, the data center 1150 includes one or more computing devices remote to the local computing device 1110 for managing a fleet of AVs and AV-related services. In certain embodiments, in addition to managing the AV 1102, the data center 1150 supports a ride-hailing service, e.g., one or more of a ridesharing service, a delivery service, a remote/roadside assistance service, and a street service such as street mapping or street patrol or street cleaning or street metering or parking reservation.

In certain embodiments, the data center 1150 sends and receives signals to and from the AV 1102 and the client computing device 1170. In certain embodiments, these signals include one or more of sensor data captured by the sensor systems 1104-1108, roadside assistance requests, software updates, and ride-hailing/ridesharing pick-up and drop-off instructions. In certain embodiments, the data center 1150 includes one or more of a data management platform 1152, an Artificial Intelligence/Machine Learning (AI/ML) platform 1154, a simulation platform 1156, a remote assistance platform 1158, and a ride-hailing platform 1160, and a map management platform 1162.

In certain embodiments, the data management platform 1152 is a “big data” system capable of receiving and transmitting data at high velocities, e.g., near-real-time or real-time, processing a large variety of data and storing large volumes, e.g., terabytes or more, of data. In certain embodiments, the data has one or more of a plurality of data structures, e.g., structured or semi-structured or unstructured, one or more of a plurality of data types, e.g., sensor data or mechanical system data or ride-hailing service data or map data or video data, data associated with one or more of a plurality of data stores, e.g., relational databases, key-value stores, document databases, graph databases, column-family databases, data analytic stores, search engine databases, time series databases, object stores, and file systems. In certain embodiments, the data originates from one or more of a plurality of sources, e.g., AVs, enterprise systems, and social networks. In certain embodiments, the data has one or more of a plurality of rates of change, e.g., batch or streaming. In certain embodiments, the various platforms and systems of the data center 1150 access data stored by the data management platform 1152 to provide their respective services.

In certain embodiments, the AI/ML platform 1154 provides the infrastructure for training and evaluating machine learning algorithms for operating one or more of the AV 1102, the simulation platform 1156, the remote assistance platform 1158, the ride-hailing platform 1160, the map management platform 1162, and other platforms and systems. In certain embodiments, the data scientists use the AI/ML platform 1154 to prepare data sets from the data management platform 1152, select and/or design and/or train machine learning models, evaluate and/or refine and/or deploy the models, and maintain and/or monitor and/or retrain the models.

In certain embodiments, the simulation platform 1156 enables testing and validation of the algorithms, machine learning models, neural networks, and other development efforts for the AV 1102, the remote assistance platform 1158, the ride-hailing platform 1160, the map management platform 1162, and other platforms and systems. In certain embodiments, the simulation platform 1156 replicates a variety of driving environments and/or reproduce real-world scenarios from data captured by the AV 1102, including rendering geospatial information and road infrastructure, e.g., crosswalks and traffic lights, obtained from a cartography platform, e.g., map management platform 1162, modeling the behavior of dynamic elements, e.g., vehicles and pedestrians, and simulating inclement weather conditions and/or different traffic scenarios.

In certain embodiments, the remote assistance platform 1158 generates and transmits instructions regarding the operation of the AV 1102. In certain embodiments, the remote assistance platform 1158 can prepare instructions for one or more stacks or other components of the AV 1102 in response to an output of the AI/ML platform 1154 or another system of the data center 1150.

In certain embodiments, the ride-hailing platform 1160 interacts with a customer of a ride-hailing service via a ride-hailing application 1172 executing on the client computing device 1170. In certain embodiments, the client computing device 1170 is any type of computing system, e.g., a server, a desktop computer, a laptop computer, a tablet computer, a smartphone, a smart wearable device such as a smartwatch or smart eyeglasses or other Head-Mounted Display (HMD), smart ear pods or other smart in-ear/on-ear/over-ear device, or a gaming system. In certain embodiments, the client computing device 1170 is a customer's mobile computing device or a computing device integrated with the AV 1102, e.g., the local computing device 1110. In certain embodiments, the ride-hailing platform 1160 receives requests to pick up or drop off from the ride-hailing application 1172 and dispatch the AV 1102 for the trip.

In certain embodiments, the map management platform 1162 provides a set of tools for the manipulation and management of geographic and spatial/geospatial and related attribute data. In certain embodiments, the data management platform 1152 receives LIDAR point cloud data, image data, e.g., a still image or video, RADAR data, GPS data, and other sensor data from one or more AVs 1102, Unmanned Aerial Vehicles (UAVs), satellites, third-party mapping services, and other sources of geospatially referenced data. In certain embodiments, the raw data is processed and map management platform 1162 renders base representations, e.g., 2D tiles or 3D bounding volumes, of the AV geospatial data to enable users to view, query, label, edit, and otherwise interact with the data. In certain embodiments, the map management platform 1162 manages workflows and tasks for operating on the AV geospatial data. In certain embodiments, the map management platform 1162 controls access to the AV geospatial data, including granting or limiting access to the AV geospatial data based on user-based, role-based, group-based, task-based, and other attribute-based access control mechanisms. In certain embodiments, the map management platform 1162 provides version control for the AV geospatial data, such as tracking specific changes that (human or machine) map editors have made to the data and to revert changes when necessary. In certain embodiments, the map management platform 1162 administers release management of the AV geospatial data, including distribution of suitable iterations of the data to different users, computing devices, AVs, and other consumers of HD maps. In certain embodiments, the map management platform 1162 provides analytics regarding the AV geospatial data and related data, e.g., generates insights relating to the throughput and quality of mapping tasks.

In certain embodiments, the map viewing services of map management platform 1162 are modularized and deployed as part of one or more of the platforms and systems of the data center 1150. In certain embodiments, the AI/ML platform 1154 incorporates map viewing services for visualizing the effectiveness of various object detection or object classification models. In certain embodiments, the simulation platform 1156 incorporates the map viewing services for recreating and visualizing certain driving scenarios. In certain embodiments, the remote assistance platform 1158 incorporates the map viewing services for replaying traffic incidents to facilitate and coordinate aid. In certain embodiments, the ride-hailing platform 1160 incorporates the map viewing services into the ride-hailing application 1172 to enable passengers to view the AV 1102 enroute to a pick-up or drop-off location.

While the autonomous vehicle 1102, the local computing device 1110, and the autonomous vehicle environment 1100 are shown to include certain systems and components, one of ordinary skill will appreciate that the autonomous vehicle 1102, the local computing device 1110, and/or the autonomous vehicle environment 1100 can include more or fewer systems and/or components than those shown in FIG. 11. In certain embodiments, the autonomous vehicle 1102 includes other services than those shown in FIG. 11. In certain embodiments, the local computing device 1110 includes one or more memory devices, e.g., RAM or ROM, one or more network interfaces, e.g., wired and/or wireless communications interfaces, and/or other hardware or processing devices that are not shown in FIG. 11.

FIG. 13 depicts example simulated return classifications for selected values of the isotropy parameter and mean free path, according to some aspects of the disclosed technology. For each emitted pulse of light, the LiDAR records either a return with a range or “no return.” In certain embodiments, the reported range comprises the strongest return. In certain embodiments, the reported return comprises the last return. The returns are classified as either a “true positive” return, e.g., there is a real target at the reported range, or a “false positive” return, e.g., there is no target at the reported range, although there may be a target in the FOV. The classified returns are plotted for the same paired values of Table 2 as FIGS. 8-10 with a target located 4 m from the LiDAR unit.

The g=0.5, MFP=0.1 plot, which is the foggiest environment, shows the largest percentage of false positive returns (48%) with another 48% of the attempted measurements being lost. Only 5% of the time did the LiDAR unit correctly report a target at 4 m. For a less dense fog (MFP=1.0) with the same refraction model (G=0.5), the plot shows a large increase in lost signals, increasing from 48% to 76%, and a reduction in false-positive signals, from 5% to 3%, the true-positive return rate climbs from 5% to 22%.

In general, the effect of the “anisotropy” parameter (g) and the fog density parameter (MFP) have the expected effects on the LiDAR return. The more-dispersive g values, e.g., near g=0.5, show a lower percentage of true-positive returns and larger proportions of lost (absorbed by the fog) and false-positive returns (returned from the fog). The less-dense MFP values, e.g., near MFP=1.0, show a higher percentage of true-positive returns and a reduction in false-positive returns.

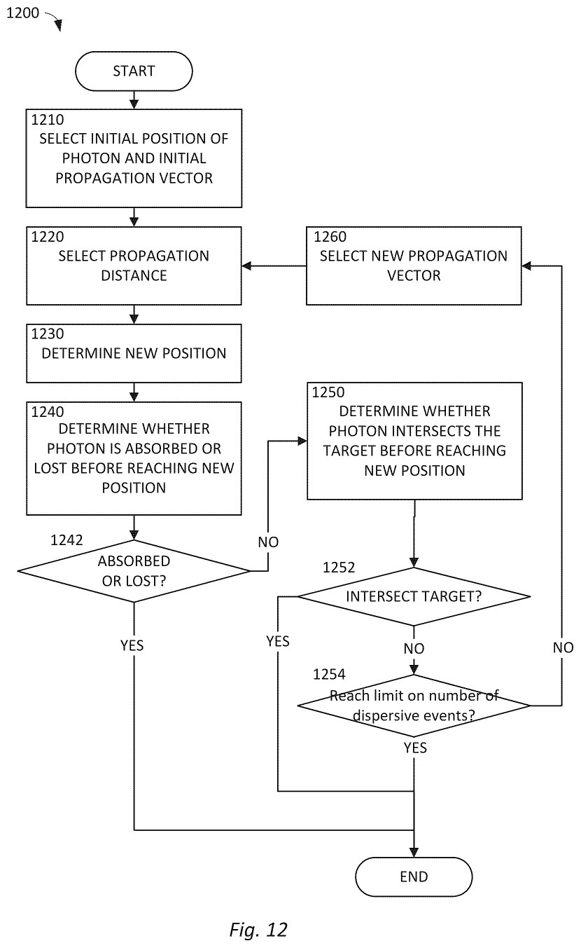

FIG. 12 depicts an example workflow 1200 for simulating a LiDAR photon path, according to some aspects of the disclosed technology. This workflow covers only the photon path from the LiDAR unit to the target, or until the photon is lost or absorbed. Determination of the path of a reflected photon will follow the same methodology starting from the final position of the outbound simulation, i.e., at the target, with an initial propagation vector based in part on the incident vector and the target characteristics, e.g., whether the photon is absorbed and whether the reflection is modeled as Lambertian or specular.

The workflow 1200 starts with a selection of an initial position and an initial propagation vector in step 1210. In general, this will be the nominal position of the LiDAR emitter and the nominal direction of the emitted light beam. A propagation distance is selected in step 1220 that is based in part on the modeled environment as described herein. Step 1230 determines a new position based on the current position, the current propagation vector, and the selected distance.

Step 1240 determines whether the photon is absorbed before it reaches the new position. In certain embodiments, this is done with a statistical model. Step 1242 branches to the end if the photon is absorbed or lost, as previously discussed, ending the simulation of this photon. In certain embodiments, a plurality of photons is simulated with common environments and targets, developing a complete statistical simulation of the LiDAR illumination beam as a combination of individual simulations of individual photos. If the photon is not absorbed, the workflow progresses to step 1250 to determine whether the photon's project path intersects the target before reaching the calculated new position. If the target is hit by the photon, the workflow branches in step 1252 to the end. The reflection of the photon will be modeled using a different process that is based in part on the final propagation vector and the target characteristics, e.g., material and surface finish and the return path of the photon will be simulated in a new process that replicates workflow 1200, treating the LiDAR receiver as the target.

If the photon reaches the new position without intersecting the target, the process branches to step 1254 to determine whether, having reached the new position, the simulation has reached a limit on the number of allowed iterations of the loop starting with step 1220. If the limit is reached, the workflow branches to the end. If the limit is not reached, the workflow branches to step 1260 that determines a new propagation vector based on a statistical simulation of the deflection of the photon by a water drop from the prior propagation vector. The process then returns to step 1220 where a new distance is selected and the subsequent steps are repeated. The simulation continues to loop back to step 1220 until the photon is lost, absorbed, or hits the target or the iteration limit of the simulation is reached.

In summary, the disclosed systems and methods provide a statistically based simulation of a single photon based on first principles and application of fundamental models of light scattering in a dispersive environment. The photon path is derived from a Monte Carlo simulation of the effect of fog on each interaction of the photon with a drop of water suspended in the fog. Photons may reach the target or be lost if they are deflected away from the target or absorbed by the fog.

In the foregoing description, aspects of the application are described with reference to specific embodiments thereof, but those skilled in the art will recognize that the application is not limited thereto. Thus, while illustrative embodiments of the application have been described in detail herein, it is to be understood that the disclosed concepts may be otherwise variously embodied and employed, and that the appended claims are intended to be construed to include such variations, except as limited by the prior art. Various features and aspects of the above-described subject matter may be used individually or jointly. Further, embodiments can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The various illustrative logical blocks, modules, circuits, and algorithm steps described in connection with the examples disclosed herein may be implemented as electronic hardware, computer software, firmware, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

In the above description, terms such as “upper,” “upward,” “lower,” “downward,” “above,” “below,” “longitudinal,” “lateral,” and the like, as used herein, are explanatory in relation to respective view of the item presented in the associated figure and are not limiting in the claimed use of the item. The term “outside” refers to a region that is beyond the outermost confines of a physical object. The term “inside” indicates that at least a portion of a region is partially contained within a boundary formed by the object.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or another word that substantially modifies, such that the component need not be exact. For example, substantially cylindrical means that the object resembles a cylinder, but can have one or more deviations from a true cylinder.

Although a variety of information was used to explain aspects within the scope of the appended claims, no limitation of the claims should be implied based on particular features or arrangements, as one of ordinary skill would be able to derive a wide variety of implementations. Further and although some subject matter may have been described in language specific to structural features and/or method steps, it is to be understood that the subject matter defined in the appended claims is not necessarily limited to these described features or acts. Such functionality can be distributed differently or performed in components other than those identified herein. The described features and steps are disclosed as possible components of systems and methods within the scope of the appended claims.

Claim language reciting “an item” or similar language indicates and includes one or more of the items. For example, claim language reciting “a part” means one part or multiple parts. Moreover, claim language reciting “at least one of” a set indicates that one member of the set or multiple members of the set satisfy the claim. For example, claim language reciting “at least one of A and B” means A, B, or A and B.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Statements of the disclosure include:
(A1) A method of simulating the effect of fog on a photon, comprising steps: (a) selecting a starting position of the photon in a 3D environment; (b) selecting a propagation vector directed from the starting position toward a target disposed in the 3D environment; (c) selecting a propagation distance; (d) determining a new position of the photon based in part on the starting position of the photon, the propagation vector, and the propagation distance; (e) determining whether the photon is absorbed before reaching the new position; and (f) determining, if the photon has not been absorbed, whether the photon intersects the target before reaching the new position, wherein the target is disposed at a predefined position in the 3D environment.
(A2) The method of A1, further comprising the steps of: (g) selecting, if the photon has not intersected the target, a deviation angle and a polar angle; (h) determining a new propagation vector based on the prior propagation vector and the selected deviation angle and the selected polar angle; (i) setting the starting position equal to the new position; and (j) repeating steps (c)-(h).
(A3) The method of A2, further comprising the steps of: modifying the new position, if the photon has intersected the target, to be located at an intersection of the propagation vector and a surface of the target.
(A4) The method of A1, wherein: the step of selecting a propagation vector comprises statistically sampling a distribution of an isotropy parameter.
(A5) The method of A1, wherein: the step of selecting a propagation distance comprises randomly selecting a value from an exponential distribution having a Mean Free Path (MFP).
(A6) The method of A1, wherein: the step of determining whether the photon is absorbed comprises randomly selecting a value from a uniform distribution over a range and conditionally evaluating the selected value against a threshold.
(A7) The method of A1, further comprising steps: counting the number of times that step (d) is performed; comparatively evaluating the count against an iteration limit; and determining that the photon is absorbed if the count exceeds the iteration limit.
(B8) A memory comprising instructions for simulating an effect of fog on a Light Detection And Ranging (LiDAR) sensor that, when loaded into a processor and executed, cause the processor to perform steps: (a) selecting a starting position of the photon in a 3D environment; (b) selecting a propagation vector directed from the starting position toward a target disposed in the 3D environment; (c) selecting a propagation distance; (d) determining a new position of the photon based in part on the starting position of the photon, the propagation vector, and the propagation distance; (e) determining whether the photon is absorbed before reaching the new position; and (f) determining, if the photon has not been absorbed, whether the photon intersects the target before reaching the new position, wherein the target is disposed at a predefined position in the 3D environment.
(B9) The memory of B8, further comprising the steps of: (g) selecting, if the photon has not intersected the target, a deviation angle and a polar angle; (h) determining a new propagation vector based on the prior propagation vector and the selected deviation angle and the selected polar angle; (i) setting the starting position equal to the new position; and (j) repeating steps (c)-(h).
(B10) The memory of B9, further comprising the steps of: modifying the new position, if the photon has intersected the target, to be located at an intersection of the propagation vector and a surface of the target.
(B11) The memory of B8, wherein: the step of selecting a propagation vector comprises statistically sampling a distribution of an isotropy parameter.
(B12) The memory of B8, wherein: the step of selecting a propagation distance comprises randomly selecting a value from an exponential distribution having a Mean Free Path (MFP).
(B13) The memory of B8, wherein: the step of determining whether the photon is absorbed comprises randomly selecting a value from a uniform distribution over a range and conditionally evaluating the selected value against a threshold.
(B14) The memory of B8, further comprising steps: counting the number of times that step (d) is performed; comparatively evaluating the count against an iteration limit; and determining that the photon is absorbed if the count exceeds the iteration limit.
(C15) A system for simulating an effect of fog on a Light Detection And Ranging (LiDAR) sensor, comprising: a processor communicatively coupled to the LiDAR sensor; and a memory communicatively coupled to the processor and comprising instructions that, when loaded into a processor and executed, cause the processor to perform steps: (a) selecting a starting position of the photon in a 3D environment; (b) selecting a propagation vector directed from the starting position toward a target disposed in the 3D environment; (c) selecting a propagation distance; (d) determining a new position of the photon based in part on the starting position of the photon, the propagation vector, and the propagation distance; (e) determining whether the photon is absorbed before reaching the new position; and (f) determining, if the photon has not been absorbed, whether the photon intersects the target before reaching the new position, wherein the target is disposed at a predefined position in the 3D environment.
(C16) The system of C15, further comprising the steps of: (g) selecting, if the photon has not intersected the target, a deviation angle and a polar angle; (h) determining a new propagation vector based on the prior propagation vector and the selected deviation angle and the selected polar angle; (i) setting the starting position equal to the new position; and (j) repeating steps (c)-(h).
(C17) The system of C16, further comprising the steps of: modifying the new position, if the photon has intersected the target, to be located at an intersection of the propagation vector and a surface of the target.
(C18) The system of C15, wherein: the step of selecting a propagation vector comprises statistically sampling a distribution of an isotropy parameter.
(C19) The system of C15, wherein: the step of selecting a propagation distance comprises randomly selecting a value from an exponential distribution having a Mean Free Path (MFP).
(C20) The system of claim 15, wherein: the step of determining whether the photon is absorbed comprises randomly selecting a value from a uniform distribution over a range and conditionally evaluating the selected value against a threshold.

What is claimed is:

1. A method of simulating the effect of fog on a photon, comprising steps:
(a) selecting a starting position of the photon in a 3D environment;
(b) selecting a propagation vector directed from the starting position toward a target disposed in the 3D environment;
(c) selecting a propagation distance;
(d) determining a new position of the photon based in part on the starting position of the photon, the propagation vector, and the propagation distance;
(e) determining whether the photon is absorbed before reaching the new position; and
(f) determining, if the photon has not been absorbed, whether the photon intersects the target before reaching the new position, wherein the target is disposed at a predefined position in the 3D environment.

2. The method of claim 1, further comprising the steps of:
(g) selecting, if the photon has not intersected the target, a deviation angle and a polar angle;
(h) determining a new propagation vector based on the prior propagation vector and the selected deviation angle and the selected polar angle;
(i) setting the starting position equal to the new position; and
(j) repeating steps (c)-(h).

3. The method of claim 2, further comprising the steps of:
modifying the new position, if the photon has intersected the target, to be located at an intersection of the propagation vector and a surface of the target.

4. The method of claim 1, wherein:
the step of selecting a propagation vector comprises statistically sampling a distribution of an isotropy parameter.

5. The method of claim 1, wherein:
the step of selecting a propagation distance comprises randomly selecting a value from an exponential distribution having a Mean Free Path (MFP).

6. The method of claim 1, wherein:
the step of determining whether the photon is absorbed comprises randomly selecting a value from a uniform distribution over a range and conditionally evaluating the selected value against a threshold.

7. The method of claim 1, further comprising steps:
counting the number of times that step (d) is performed;
comparatively evaluating the count against an iteration limit; and
determining that the photon is absorbed if the count exceeds the iteration limit.

8. A memory comprising instructions for simulating an effect of fog on a Light Detection And Ranging (LiDAR) sensor that, when loaded into a processor and executed, cause the processor to perform steps:
(a) selecting a starting position of the photon in a 3D environment;
(b) selecting a propagation vector directed from the starting position toward a target disposed in the 3D environment;
(c) selecting a propagation distance;
(d) determining a new position of the photon based in part on the starting position of the photon, the propagation vector, and the propagation distance;
(e) determining whether the photon is absorbed before reaching the new position; and
(f) determining, if the photon has not been absorbed, whether the photon intersects the target before reaching the new position, wherein the target is disposed at a predefined position in the 3D environment.

9. The memory of claim 8, further comprising the steps of:
(g) selecting, if the photon has not intersected the target, a deviation angle and a polar angle;
(h) determining a new propagation vector based on the prior propagation vector and the selected deviation angle and the selected polar angle;
(i) setting the starting position equal to the new position; and
(j) repeating steps (c)-(h).

10. The memory of claim 9, further comprising the steps of:
modifying the new position, if the photon has intersected the target, to be located at an intersection of the propagation vector and a surface of the target.

11. The memory of claim 8, wherein:
the step of selecting a propagation vector comprises statistically sampling a distribution of an isotropy parameter.

12. The memory of claim 8, wherein:
the step of selecting a propagation distance comprises randomly selecting a value from an exponential distribution having a Mean Free Path (MFP).

13. The memory of claim 8, wherein:
the step of determining whether the photon is absorbed comprises randomly selecting a value from a uniform distribution over a range and conditionally evaluating the selected value against a threshold.

14. The memory of claim 8, further comprising steps:
counting the number of times that step (d) is performed;
comparatively evaluating the count against an iteration limit; and
determining that the photon is absorbed if the count exceeds the iteration limit.

15. A system for simulating an effect of fog on a Light Detection And Ranging (LiDAR) sensor, comprising:
a processor communicatively coupled to the LiDAR sensor; and
a memory communicatively coupled to the processor and comprising instructions that, when loaded into a processor and executed, cause the processor to perform steps:
(a) selecting a starting position of the photon in a 3D environment;
(b) selecting a propagation vector directed from the starting position toward a target disposed in the 3D environment;
(c) selecting a propagation distance;
(d) determining a new position of the photon based in part on the starting position of the photon, the propagation vector, and the propagation distance;
(e) determining whether the photon is absorbed before reaching the new position; and
(f) determining, if the photon has not been absorbed, whether the photon intersects the target before reaching the new position, wherein the target is disposed at a predefined position in the 3D environment.

16. The system of claim 15, further comprising the steps of:
(g) selecting, if the photon has not intersected the target, a deviation angle and a polar angle;
(h) determining a new propagation vector based on the prior propagation vector and the selected deviation angle and the selected polar angle;
(i) setting the starting position equal to the new position; and
(j) repeating steps (c)-(h).

17. The system of claim 16, further comprising the steps of:
modifying the new position, if the photon has intersected the target, to be located at an intersection of the propagation vector and a surface of the target.

18. The system of claim 15, wherein:
the step of selecting a propagation vector comprises statistically sampling a distribution of an isotropy parameter.

19. The system of claim 15, wherein:
the step of selecting a propagation distance comprises randomly selecting a value from an exponential distribution having a Mean Free Path (MFP).

20. The system of claim 15, wherein:
the step of determining whether the photon is absorbed comprises randomly selecting a value from a uniform distribution over a range and conditionally evaluating the selected value against a threshold.
